(19) United States
(12) Patent Application Publication
(10) Pub. No.: US 2022/0232733 A1
(43) Pub. Date: Jul. 21, 2022

(54) COOLING DEVICE FOR HEAT EXCHANGE OF CPU RADIATOR

(71) Applicant: BEIJING DEEPCOOL INDUSTRIES CO., LTD., BEIJING (CN)

(72) Inventor: Weichao LI, Beijing (CN)

(21) Appl. No.: 17/715,982

(22) Filed: Apr. 8, 2022

Related U.S. Application Data
(63) Continuation of application No. PCT/CN2020/116522, filed on Sep. 21, 2020.

(30) Foreign Application Priority Data
Oct. 25, 2019 (CN) 201911024557.8

(51) Int. Cl. H05K 7/20; G06F 1/20

(52) U.S. Cl. CPC H05K 7/20272; G06F 1/20; H05K 7/20263

(57) ABSTRACT

A cooling device for heat exchange of a CPU radiator includes a radiating copper bottom, arranged at the bottom of the cooling device; a shell, arranged above the radiating copper bottom and internally provided with a compound cavity, the compound cavity comprising an impeller cavity and a heat exchange cavity that are arranged vertically and are separated via a horizontal wall, the impeller cavity being located above the heat exchange cavity; an impeller, arranged in the impeller cavity, an impeller cover being arranged above the shell; and a motor wire group, arranged on the impeller cover, wherein the heat exchange cavity and the impeller cavity are communicated via at least one pipeline arranged on a side wall of the heat exchange cavity, and the side wall of the heat exchange cavity is separated from the horizontal wall via a step.

### FIELD OF TECHNOLOGY

The present invention relates to the technical field of CPU radiators, in particular to a cooling device for heat exchange of a CPU radiator.

### BACKGROUND

With rapid development of electronics technology and information network technology, computers have become an indispensable part in people's daily life. While electronics technology has been developed rapidly, the performance of the computer has been improved rapidly. The quantity of heat of parts in the computer is increased while the performance is improved, which affects the performance and the service life of the computer severely.

A water-cooling radiator generally used for radiation of a computer CPU performs radiation by means of circulation of a cooling liquid. The water-cooling radiator includes a water-cooling pump head, a pipeline and a radiating bar and the like. The water-cooling pump head in the prior art includes a heat exchange cavity and a pump cavity that are separated by a horizontal wall, and the cooling liquid is communicated with a radiating cavity and the pump cavity via a pipeline vertically arranged on the horizontal wall to achieve a purpose of circular radiation. However, there are constraints by way of the pump cavity and the heat exchange cavity that are communicated via the horizontal wall, leading to problems such as a narrow part communicated with the pipeline and the like, thereby, affecting the radiating effect.

Information disclosed in this background art is merely intended to enhance understanding of the general background of the present invention and shall not be taken as an acknowledgment or any form of suggestion that this information forms the prior art already known to those of ordinary skill in the art.

### SUMMARY

The present invention is intended to provide a cooling device for heat exchange of a CPU radiator, which can overcome the above-mentioned problems in the prior art.

In order to achieve the above-mentioned objective, the present invention provides a cooling device for heat exchange of a CPU radiator. The cooling device for heat exchange of the CPU radiator comprises a radiating copper bottom, arranged at the bottom of the cooling device; a shell, arranged above the radiating copper bottom and internally provided with a compound cavity, the compound cavity comprising an impeller cavity and a heat exchange cavity that are arranged vertically and are separated via a horizontal wall, the impeller cavity being located above the heat exchange cavity; an impeller, arranged in the impeller cavity, an impeller cover being arranged above the shell; and a motor wire group, arranged on the impeller cover, where the heat exchange cavity and the impeller cavity are communicated via at least one pipeline arranged on a side wall of the heat exchange cavity, and the side wall of the heat exchange cavity is separated from the horizontal wall via a step.

In a preferred implementation mode, the impeller cavity and the heat exchange cavity are of an integrated structure by means of injection molding, the impeller cavity is internally provided with an upper water opening and a lower water opening, the upper water opening is communicated with one of the pipelines arranged on a side wall of the heat exchange cavity, the lower water opening is communicated with another one of the pipelines arranged on the side wall of the heat exchange cavity, and an inlet of the upper water opening and an outlet of the lower water opening are respectively formed on the side wall of the heat exchange cavity.

In a preferred implementation mode, an outer side surface of the shell is provided with a first water inlet and a first water outlet, the first water inlet and the first water outlet being respectively connected with an external water inlet nozzle and an external water outlet nozzle.

In a preferred implementation mode, the device further includes a guide plate, arranged in the heat exchange cavity, a front surface of the guide plate being provided with a water inlet channel, a water discharging channel and a first water outlet channel, a center of a back surface of the guide plate being provided with a second water outlet channel, and two sides of the guide plate being respectively provided with second water inlets, where the water inlet channel is communicated with the first water inlet, the water discharging channel is communicated with the first water outlet channel, the water inlet channel is communicated with the second water outlet channels, and the first water outlet channel is provided with two second water outlets.

In a preferred implementation mode, a cooling liquid can flow in from the first water inlet and flows into an absorber plate on the radiating copper bottom via the water inlet channel and the second water outlet channels for heat exchange, the cooling liquid subject to heat exchange is imported into one of the pipelines respectively via the two second water inlets, the first water outlet channel and the inlet of the upper water opening and enters the impeller cavity, and the cooling liquid pressurized by the impeller can enter the water discharging channel via the lower water opening, the another one of the pipelines and the outlet of the lower water opening and flows out via the first water outlet.

In a preferred implementation mode, a middle position of the impeller cavity is provided with a groove, the groove is used for storing the cooling liquid and is internally provided with a water stop sheet, a center of the water stop sheet is provided with a through hole, and the water stop sheet is used for guiding an inflow on a side to the center.

In a preferred implementation mode, the water stop sheet covers the upper water opening and the side of the water stop sheet close to the upper water opening is provided with a vertical baffle.

In a preferred implementation mode, the impeller cover is internally provided with a center shaft, one end of the center shaft is connected with a top inner wall of the impeller cover, and the other end of the center shaft passes through the center of the impeller and is arranged in the through hole of the water stop sheet.

In a preferred implementation mode, a diameter of the through hole is greater than a diameter of the center shaft.

In a preferred implementation mode, a soft film is arranged between the guide plate and the absorber plate on the radiating copper bottom, seal rings are arranged between the impeller cover and the shell and between the shell and the radiating copper bottom, and the bottom of the radiating copper bottom is provided with a threaded seal ring.

Compared with the prior art, the cooling device for heat exchange of a CPU radiator according to the present invention has the following advantages: the horizontal wall is separated from the side wall obviously with a right-angled through connection and the step, and thus, the horizontal wall and the side wall are differentiated fundamentally; the communicating pipeline between the heat exchange cavity and the impeller cavity of the present invention is arranged on the side wall of the heat exchange cavity to avoid shortcomings in the prior art, and the present invention provides a sufficient space for the communicating pipeline, and thus, the cooling liquid performs heat exchange more efficiently.

### BRIEF DESCRIPTION OF THE DRAWINGS

FIG. 1 is a front view schematic diagram of a cooling device according to an implementation mode of the present invention.

FIG. 2 is an internal three-dimensional structural diagram of a cooling device according to an implementation mode of the present invention.

FIG. 3 is an internal three-dimensional structural diagram of a cooling device according to an implementation mode of the present invention in another direction.

FIG. 4 is an exploded view of a cooling device according to an implementation mode of the present invention.

FIG. 5 is a three-dimensional structural diagram of a shell according to an implementation mode of the present invention.

FIG. 6 is a front view of a shell according to an implementation mode of the present invention.

FIG. 7 is a top view of a shell according to an implementation mode of the present invention.

FIG. 8 is a section view of FIG. 6 in a B-B direction.

FIG. 9 is a section view of FIG. 6 in an A-A direction.

FIG. 10 is a bottom view three-dimensional structural diagram of a shell according to an implementation mode of the present invention.

FIG. 11 is a three-dimensional structural diagram of a guide plate according to an implementation mode of the present invention.

FIG. 12 is a front view schematic diagram of a guide plate according to an implementation mode of the present invention.

FIG. 13 is a back schematic diagram of a guide plate according to an implementation mode of the present invention.

FIG. 14 is a three-dimensional structural diagram of a water stop sheet according to an implementation mode of the present invention.

FIG. 15 is an internal three-dimensional structural diagram of an impeller cover according to an implementation mode of the present invention.

### DESCRIPTION OF MAIN NUMERALS OF THE DRAWINGS

1—radiating copper bottom; 2—shell; 3—impeller; 4—impeller cover; 5—motor wire group; 6—compound cavity; 7—horizontal wall; 8—impeller cavity; 9—heat exchange cavity; 10—side wall of heat exchange cavity; 11—upper water opening; 12—lower water opening; 13—inlet of upper water opening; 14—first water inlet; 15—first water outlet; 16—guide plate; 17—water inlet channel; 18—water discharging channel; 19—first water outlet channel; 20—second water outlet channel; 21—second water inlet; 22—second water outlet; 23—groove; 24—water stop sheet; 25—soft film; 29—absorber plate; 30—vertical baffle.

### DESCRIPTION OF THE EMBODIMENTS

Detailed description on the specific implementation modes of the present invention is made below in combination with the drawings, and it shall be understood that the scope of protection of the present invention is not limited by the specific implementation modes.

Unless otherwise expressly indicated, terms “include” or its transformation such as “comprise” or “consist of” throughout the description and claims will be understood to include stated elements or components but rather than excludes other elements or components.

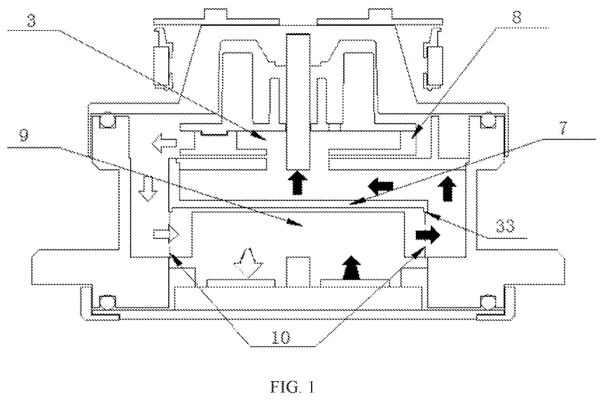

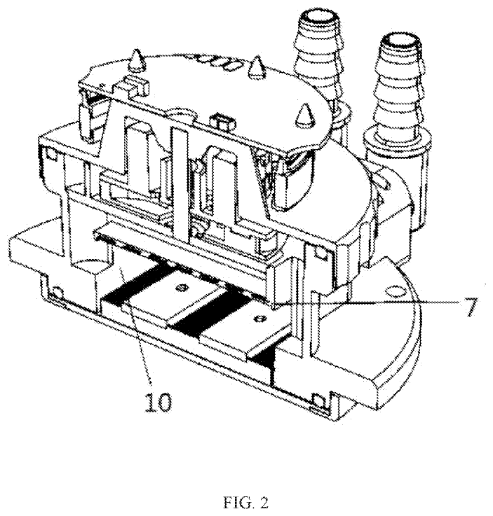

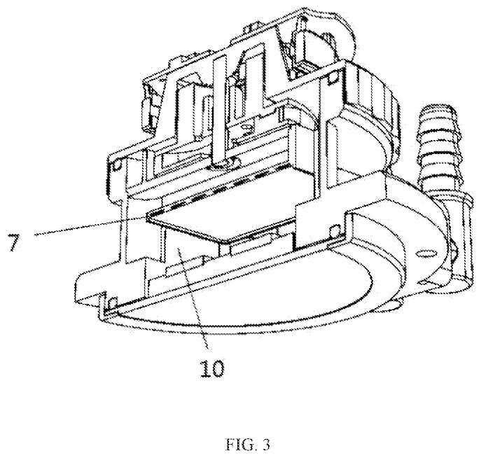

As shown in FIG. 1 to FIG. 4, the cooling device for heat exchange of a CPU radiator according to the preferred implementation mode includes a radiating copper bottom 1, a shell 2, an impeller 3, an impeller cover 4 and a motor wire group 5, where the radiating copper bottom 1 is arranged at the bottom of the cooling device; the shell 2 is arranged above the radiating copper bottom 1 and is fixedly connected with the radiating copper bottom 1, and the shell 2 is internally provided with a compound cavity 6, the compound cavity 6 including an impeller cavity 8 and a heat exchange cavity 9 that are arranged vertically and are separated via a horizontal wall 7, the impeller cavity 8 being located above the heat exchange cavity 9; the impeller 3 is arranged in the impeller cavity 8, the impeller cover 4 is arranged above the shell, and the motor wire group 5 is arranged on the impeller cover 4. The heat exchange cavity 9 and the impeller cavity 8 are communicated via at least one pipeline arranged on a side wall 10 of the heat exchange cavity, and the side wall 10 of the heat exchange cavity and the horizontal wall 7 are separated obviously, for example, by a step 33 shown in FIG. 1.

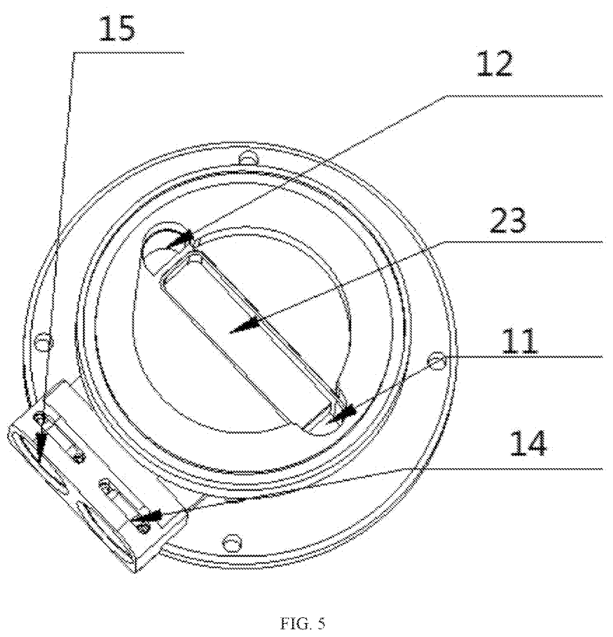

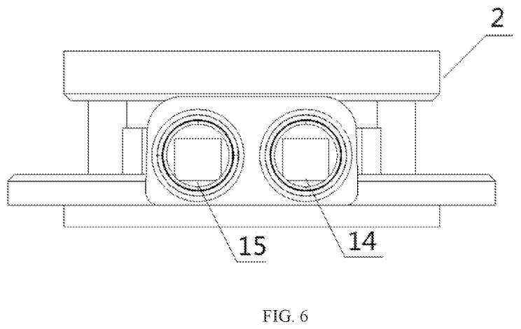

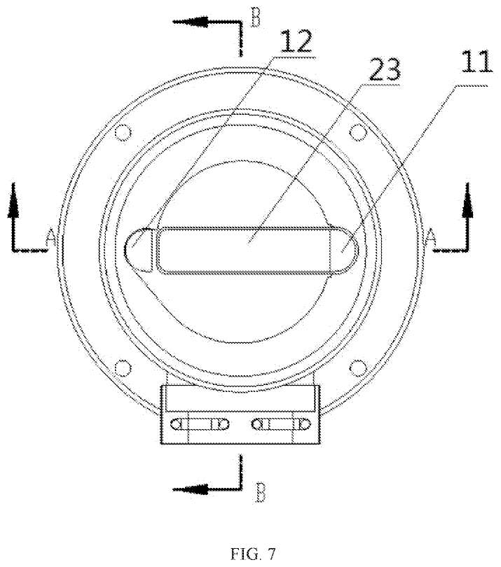

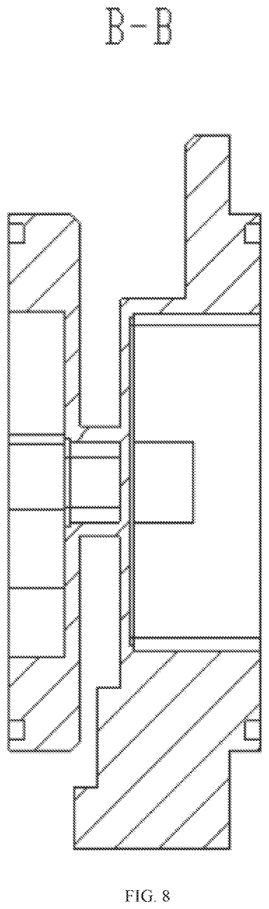

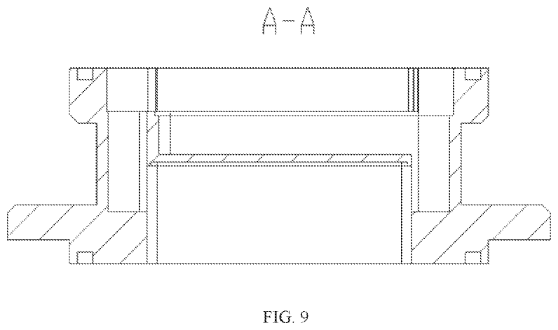

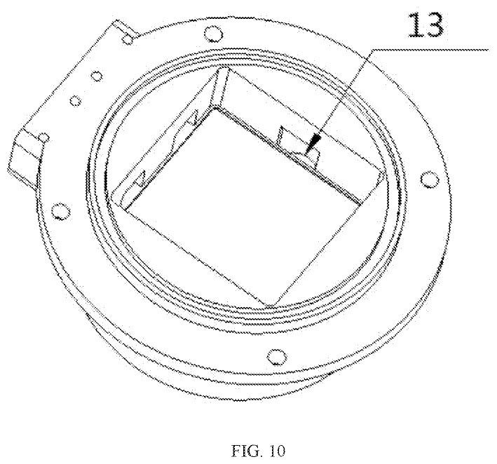

Preferably, the impeller cavity and the heat exchange cavity are of an integrated structure by injection molding. As separated structures are optimized to an integrally formed structure, a risk of connecting leakage is avoided, and thus, the cost is saved. Referring to FIG. 5 to FIG. 10, the impeller cavity 8 is internally provided with an upper water opening 11 and a lower water opening 12, the upper water opening 11 and the lower water opening 12 are not in the same horizontal plane, and the lower water opening 12 is higher than the upper water opening 11, where the upper water opening 11 is communicated with one of the pipelines arranged on the side wall 10 of the heat exchange cavity, the lower water opening 12 is communicated with another one of the pipelines arranged on the side wall 10 of the heat exchange cavity, and an inlet 13 of the upper water opening and an outlet of the lower water opening are respectively formed on the side wall 10 of the heat exchange cavity. An outer side surface of the shell 2 is provided with a first water inlet 14 and a first water outlet 15, the first water inlet 14 and the first water outlet 15 being respectively connected with an external water inlet nozzle and an external water outlet nozzle.

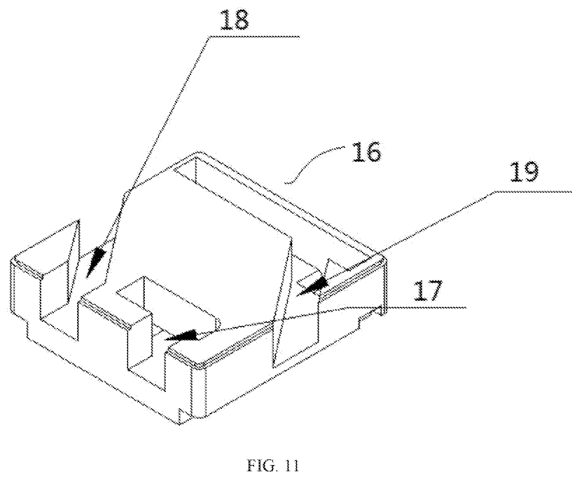

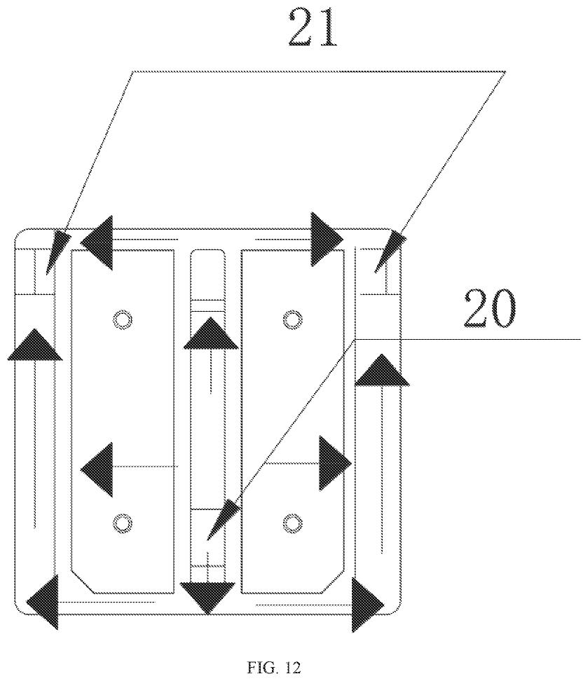

Referring to FIG. 11 to FIG. 13, the cooling device further includes a guide plate 16, arranged in the heat exchange cavity, a front surface of the guide plate 16 being provided with a water inlet channel 17, a water discharging channel 18 and a first water outlet channel 19, a center of a back surface of the guide plate 16 being provided with a second water outlet channel 20, and two sides of the guide plate being respectively provided with second water inlets 21, where the water inlet channel 17 is communicated with the first water inlet 14, the water discharging channel 18 is communicated with the first water outlet channel 15, the water inlet channel 17 is communicated with the second water outlet channel 20, and the first water outlet channel is provided with two second water outlets 22.

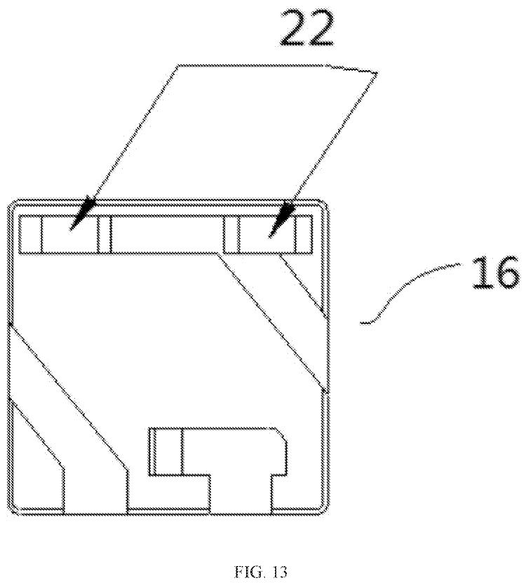

Referring to FIG. 0.1 to FIG. 13 again, a working process of the cooling device of the present invention is as follows: a cooling liquid can flow in from the first water inlet 14 and flows into an absorber plate 29 on the radiating copper bottom via the water inlet channel 17 and the second water outlet channel 20 for heat exchange, the cooling liquid subject to heat exchange is imported into one of the pipelines on the side wall of the heat exchange cavity respectively via the two second water inlets 21, the first water outlet channel 19 and the inlet 13 of the upper water opening and enters the impeller cavity 8, and the cooling liquid pressurized by the impeller can enter the water discharging channel 18 via the lower water opening 12, the another one of the pipelines on the side wall of the heat exchange cavity and the outlet of the lower water opening and flows out via the first water outlet 15.

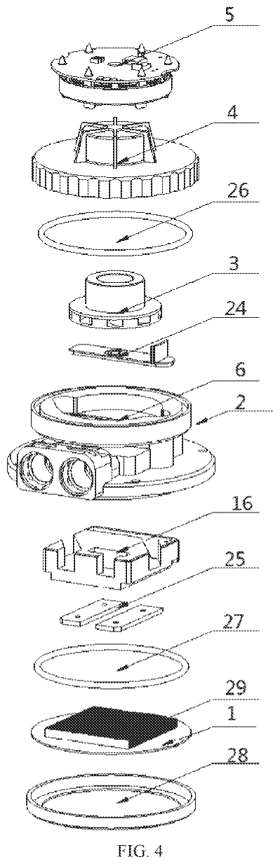

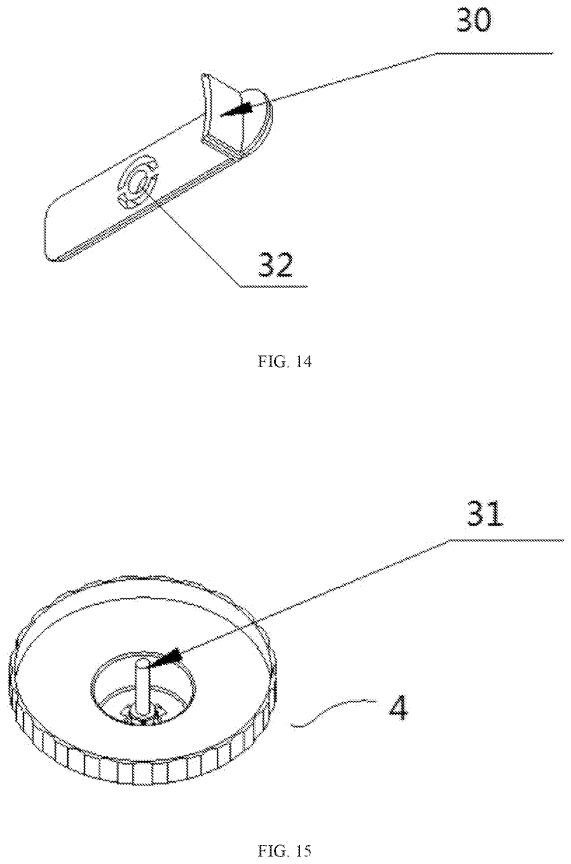

Referring to FIG. 4 and FIG. 14, a middle position of the impeller cavity is provided with a groove 23, the groove 23 is used for storing the cooling liquid, a water stop sheet 24 is arranged above the groove 23, and a center of the water stop sheet 24 is provided with a through hole 32. The water stop sheet 24 covers the upper water opening 11 and the side of the water stop sheet 24 close to the upper water opening is provided with a vertical baffle 30. Referring to FIG. 14 to FIG. 15, the impeller cover 4 is internally provided with a center shaft 31, one end of the center shaft 31 is connected with a top inner wall of the impeller cover, and the other end of the center shaft 31 passes through the center of the impeller and is arranged in the through hole 32 of the water stop sheet. A diameter of the through hole 32 is greater than a diameter of the center shaft 31, and the water stop sheet 24 can guide an inflow on a side to the center.

Referring to FIG. 4, a soft film 25 is arranged between the guide plate 16 and the absorber plate 29 on the radiating copper bottom, a first seal ring 26 is arranged between the impeller cover 4 and the shell 2, a second seal ring 27 is arranged between the shell 2 and the radiating copper bottom 1, and the bottom of the radiating copper bottom 1 is provided with a threaded seal ring 28, thereby, the sealing performance and the reliability of a water block are improved remarkably.

The above specific exemplary embodiments of the present invention are described for purposes of example illustration and description. These descriptions are not intended to limit the invention to the precise forms disclosed, and obviously many modifications and variations are possible in light of the above teaching. The exemplary embodiments are chosen and described in order to explain certain principles of the invention and their practical applications, thereby, enabling those skilled in the art to make and utilize various exemplary embodiments of the present invention, as well as various different alternatives and modifications thereof. The scope of the present invention is intended to be defined by the claims and equivalents thereof.

What is claimed is:

1. A cooling device for heat exchange of a CPU radiator, the cooling device for heat exchange of a CPU radiator comprising:
a radiating copper bottom, arranged at the bottom of the cooling device;
a shell, arranged above the radiating copper bottom and internally provided with a compound cavity, the compound cavity comprising an impeller cavity and a heat exchange cavity that are arranged vertically and are separated via a horizontal wall, the impeller cavity being located above the heat exchange cavity;
an impeller, arranged in the impeller cavity, an impeller cover being arranged above the shell; and
a motor wire group, arranged on the impeller cover;
wherein the heat exchange cavity and the impeller cavity are communicated via at least one pipeline arranged on a side wall of the heat exchange cavity, and the side wall of the heat exchange cavity is separated from the horizontal wall via a step.

2. The cooling device of claim 1, wherein the impeller cavity and the heat exchange cavity are of an integrated structure by means of injection molding, the impeller cavity is internally provided with an upper water opening and a lower water opening, the upper water opening is communicated with one of the pipelines arranged on a side wall of the heat exchange cavity, the lower water opening is communicated with another one of the pipelines arranged on the side wall of the heat exchange cavity, and an inlet of the upper water opening and an outlet of the lower water opening are respectively formed on the side wall of the heat exchange cavity.

3. The cooling device of claim 2, wherein an outer side surface of the shell is provided with a first water inlet and a first water outlet, the first water inlet and the first water outlet being respectively connected with an external water inlet nozzle and an external water outlet nozzle.

4. The cooling device of claim 3, further comprising a guide plate, arranged in the heat exchange cavity, a front surface of the guide plate being provided with a water inlet channel, a water discharging channel and a first water outlet channel, a center of a back surface of the guide plate being provided with a second water outlet channel, and two sides of the guide plate being respectively provided with second water inlets, wherein the water inlet channel is communicated with the first water inlet, the water discharging channel is communicated with the first water outlet channel, the water inlet channel is communicated with the second water outlet channel, and the first water outlet channel is provided with two second water outlets.

5. The cooling device of claim 4, wherein a cooling liquid can flow in from the first water inlet and flows into an absorber plate on the radiating copper bottom via the water inlet channel and the second water outlet channels for heat exchange, the cooling liquid subject to heat exchange is imported into one of the pipelines respectively via the two second water inlets, the first water outlet channel and the inlet of the upper water opening and enters the impeller cavity, and the cooling liquid pressurized by the impeller can enter the water discharging channel via the lower water opening, the another one of the pipelines and the outlet of the lower water opening and flows out via the first water outlet.

6. The cooling device of claim 2, wherein a middle position of the impeller cavity is provided with a groove, the groove is used for storing the cooling liquid and is internally provided with a water stop sheet, a center of the water stop sheet is provided with a through hole, and the water stop sheet is used for guiding an inflow on a side to the center.

7. The cooling device of claim 4, wherein the water stop sheet covers the upper water opening and the side of the water stop sheet close to the upper water opening is provided with a vertical baffle.

8. The cooling device of claim 6, wherein the impeller cover is internally provided with a center shaft, one end of the center shaft is connected with a top inner wall of the impeller cover, and the other end of the center shaft passes through the center of the impeller and is arranged in the through hole of the water stop sheet.

9. The cooling device of claim 8, wherein a diameter of the through hole is greater than a diameter of the center shaft.

10. The cooling device of claim 4, wherein a soft film is arranged between the guide plate and the absorber plate on the radiating copper bottom, seal rings are arranged between the impeller cover and the shell and between the shell and the radiating copper bottom, and the bottom of the radiating copper bottom is provided with a threaded seal ring.
